(19) United States
(12) Patent Application Publication
(10) Pub. No.: US 2015/0372003 A1
(43) Pub. Date: Dec. 24, 2015

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/638,493

(22) Filed: Mar. 4, 2015

(30) Foreign Application Priority Data
Jun. 24, 2014 (JP) 2014-129028

(51) Int. Cl. H01L 27/115; H01L 21/285; H01L 21/311; H01L 21/28

(52) U.S. Cl. CPC H01L 27/11582; H01L 21/28282; H01L 21/28518; H01L 21/31105

(57) ABSTRACT

According to one embodiment, a nonvolatile semiconductor memory device, includes: a foundation layer; a stacked body provided on the foundation layer, each of a plurality of first insulating layers and each of a plurality of electrode layers being stacked alternately in the stacked body; a first layer provided between the stacked body and the foundation layer, the first layer including semiconductor, one portion of the first layer on a side of the stacked body including metal; a pair of first semiconductor members extending through the stacked body in a stacking direction of the stacked body; a memory film provided between each of the first semiconductor members and each of the plurality of electrode layers; a second semiconductor member provided inside the first layer and connected to the pair of first semiconductor members; and an insulating film provided between the second semiconductor member and the first layer.

### CROSS-REFERENCE TO RELATED APPLICATIONS

This application is based upon and claims the benefit of priority from Japanese Patent Application No. 2014-129028, filed on Jun. 24, 2014; the entire contents of which are incorporated herein by reference.

### FIELD

Embodiments described herein relate generally to a nonvolatile semiconductor memory device and a method for manufacturing the same.

### BACKGROUND

There is a nonvolatile semiconductor memory device that is manufactured by forming a stacked body including alternately-stacked control gate layers and insulating layers on a semiconductor layer, making a memory hole in the stacked body, forming a memory film on an inner wall of the memory hole, and further forming a channel body layer. There are cases where the memory capacity is increased by patterning the memory hole into a U-shaped configuration.

Here, a transistor is formed of the semiconductor layer, the channel body layer, and the insulating film at the portion where the memory hole is bent into the U-shaped configuration. The transistor of this portion is called, for example, a back gate transistor. The semiconductor layer is used as the gate electrode of the back gate transistor; and it is desirable to reduce the resistance of the gate electrode (the semiconductor layer) to improve the controllability of the transistor.

### BRIEF DESCRIPTION OF THE DRAWINGS

FIG. 1A is a schematic cross-sectional view showing a nonvolatile semiconductor memory device according to a first embodiment, and FIG. 1B is a schematic plan view showing the nonvolatile semiconductor memory device according to the first embodiment;

FIG. 2A to FIG. 14 are schematic cross-sectional views showing manufacturing processes of the nonvolatile semiconductor memory device according to the first embodiment;

FIG. 15A to FIG. 17 are schematic cross-sectional views showing manufacturing processes of a nonvolatile semiconductor memory device according to a second embodiment; and

FIG. 18A to FIG. 23 are schematic cross-sectional views showing manufacturing processes of a nonvolatile semiconductor memory device according to a third embodiment.

### DETAILED DESCRIPTION

In general, according to one embodiment, a nonvolatile semiconductor memory device, includes: a foundation layer; a stacked body provided on the foundation layer, each of a plurality of first insulating layers and each of a plurality of electrode layers being stacked alternately in the stacked body; a first layer provided between the stacked body and the foundation layer, the first layer including semiconductor, one portion of the first layer on a side of the stacked body including metal; a pair of first semiconductor members extending through the stacked body in a stacking direction of the stacked body; a memory film provided between each of the first semiconductor members and each of the plurality of electrode layers; a second semiconductor member provided inside the first layer and connected to the pair of first semiconductor members; and an insulating film provided between the second semiconductor member and the first layer.

Embodiments will now be described with reference to the drawings. In the description hereinbelow, the same members are marked with the same reference numerals; and a description is omitted as appropriate for members once described.

### First Embodiment

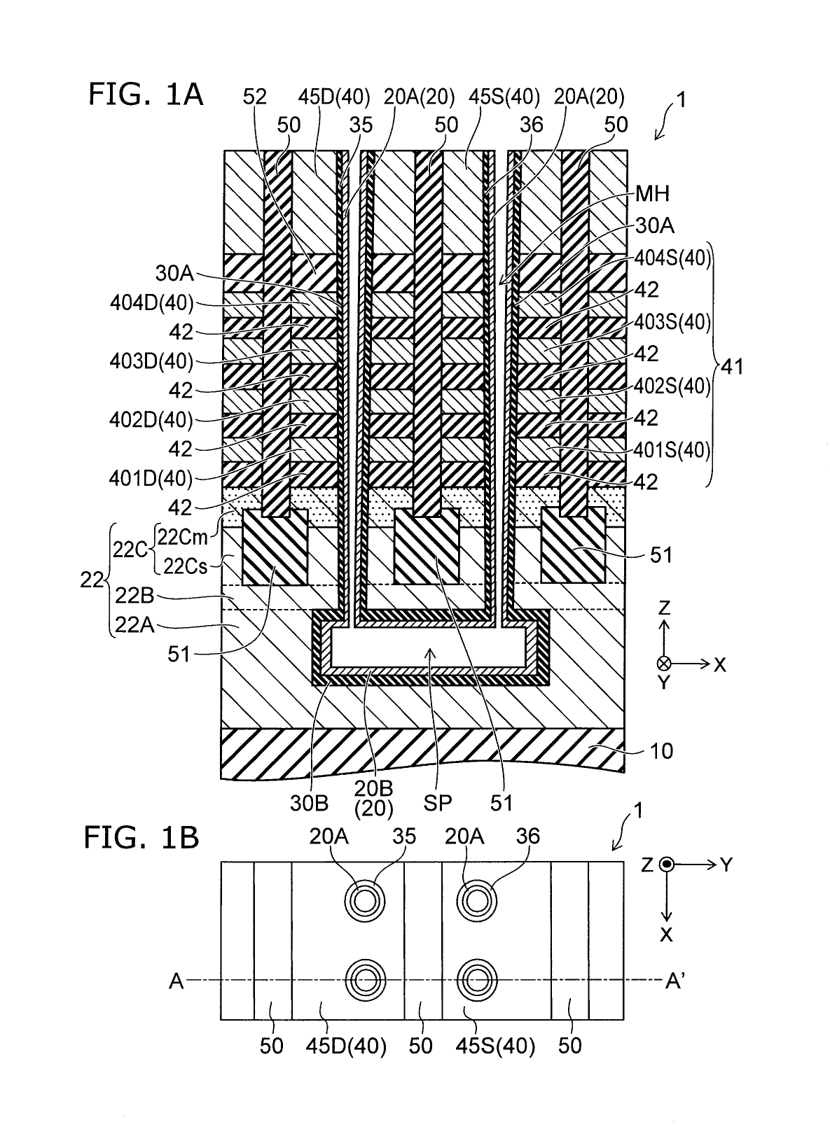

FIG. 1A is a schematic cross-sectional view showing a nonvolatile semiconductor memory device according to a first embodiment; and FIG. 1B is a schematic plan view showing the nonvolatile semiconductor memory device according to the first embodiment.

FIG. 1A is a cross section at a position along line A-A′ of FIG. 1B.

For convenience of description, an XYZ orthogonal coordinate system is introduced to FIGS. 1A and 1B. In the coordinate system, two mutually-orthogonal directions parallel to a major surface of a foundation layer 10 are taken as an X-direction and a Y-direction; and a direction orthogonal to both the X-direction and the Y-direction is taken as a Z-direction.

The nonvolatile semiconductor memory device 1 is a NAND nonvolatile memory that can freely and electrically erase and program data and retain the memory content even when the power supply is OFF. The nonvolatile semiconductor memory device 1 shown in FIGS. 1A and 1B is normally called BiCS (Bit Cost Scalable) flash memory.

In the nonvolatile semiconductor memory device 1, a back gate electrode 22 is provided on a foundation layer 10. The back gate electrode 22 is, for example, a layer in which back gate electrode portions 22A, 22B, and 22C are overlaid.

The back gate electrode portion 22C includes a back gate electrode portion 22Cs and a back gate electrode portion 22Cm. That is, a portion of the back gate electrode portion 22C is the back gate electrode portion 22Cm.

The back gate electrode portion 22Cm includes metal by siliciding. The back gate electrode portion 22Cm is provided on a side of a stacked body 41. The back gate electrode portion 22Cm is in contact with the stacked body 41. The back gate electrode portion 22Cm is in contact with an insulating layer 51. The back gate electrode portion 22Cs is a layer not being silicided.

The back gate electrode portions 22A, 22B, and 22C are generally called a semiconductor-containing layer (a layer including semiconductor). The back gate electrode 22 is, for example, a silicon-containing layer or a silicon (Si)-containing layer to which an impurity element is added. The back gate electrode 22 includes the insulating layer 51 (a second insulating layer) in the interior of the back gate electrode 22.

Thus, the back gate electrode portion 22Cm in the back gate electrode 22 is silicided. The back gate electrode portion 22Cm exists on the insulating layer 51.

That is, the region of the back gate electrode 22 between the insulating layer 51 and the stacked body 41 is silicided; and a portion of the back gate electrode 22 extending over the interior of the back gate electrode 22 from the region is silicided. In other words, the back gate electrode portion 22Cm that is positioned on the insulating layer 51 is silicided; and the portion of the back gate electrode portion 22Cm interposed between mutually-adjacent insulating layers 51 is silicided.

For example, the back gate 22Cm prior to being silicided has the same components as the back gate electrode portions 22A, 22B, and 22Cs.

For example, the foundation layer 10 includes an insulator. A semiconductor substrate (not shown) is provided under the foundation layer 10. Active elements such as transistors, etc., passive elements such as resistors, capacitors, etc., may be provided in the semiconductor substrate. Interconnects that are linked to these elements may be drawn out in the foundation layer 10.

Electrode layers 401D, 402D, 403D, and 404D on the drain side and electrode layers 401S, 402S, 403S, and 404S on the source side are stacked on the back gate electrode 22. An insulating layer 42 (a first insulating layer) is provided between the electrode layers above and below. The insulating layer 42 includes, for example, silicon oxide, silicon nitride, etc.

An insulating layer 50 is provided between the electrode layer 401D and the electrode layer 401S, between the electrode layer 402D and the electrode layer 402S, between the electrode layer 403D and the electrode layer 403S, and between the electrode layer 404D and the electrode layer 404S. The insulating layer 50 includes, for example, silicon oxide, silicon nitride, etc.

The number of layers of the electrode layers 401D to 404D or the electrode layers 401S to 404S are arbitrary and are not limited to the numbers shown in FIG. 1A. The electrode layers 401D to 404D and 401S to 404S may be generally referred to as an electrode layer 40. The electrode layer 40 is, for example, a silicon-containing layer to which an impurity element such as boron (B), etc., is added. The electrode layer is conductive. The structural body provided on the foundation layer 10 in which each of the multiple insulating layers 42 and each of the multiple electrode layers 40 are stacked alternately is referred to as the stacked body 41.

The insulating layer 51 is provided between the stacked body 41 and the foundation layer 10. The insulating layer 51 includes, for example, silicon oxide, silicon nitride, tantalum oxide, etc. The insulating layer 51 is provided in the interior of the back gate electrode 22. The insulating layer 51 is positioned between the stacked body 41 and the foundation layer 10.

A selection gate electrode 45D on the drain side is provided on the electrode layer 404D via an insulating layer 52. The insulating layer 52 includes, for example, silicon oxide, silicon nitride, etc. The selection gate electrode 45D is, for example, a conductive silicon-containing layer to which an impurity is added. A gate insulator film 35 is provided between a channel body layer 20A (the first semiconductor member) and the selection gate electrode 45D. A selection transistor on the drain side is formed of the selection gate electrode 45D, the channel body layer 20A, and the gate insulator film 35.

A selection gate electrode 45S on the source side is provided on the electrode layer 404S via the insulating layer 52. The selection gate electrode 45S is, for example, a conductive silicon-containing layer to which an impurity is added. A gate insulator film 36 is provided between the channel body layer 20A and the selection gate electrode 45S. A selection transistor on the source side is formed of the selection gate electrode 45S, the channel body layer 20A, and the gate insulator film 36.

The selection gate electrode 45D and the selection gate electrode 45S are separated in the Y-direction by the insulating layer 50. The selection gate electrode 45D and the selection gate electrode 45S may be generally referred to as a selection gate electrode 45. The selection gate electrode 45D is connected to a bit line (not shown) of the nonvolatile semiconductor memory device; and the selection gate electrode 45S is connected to a source line (not shown) of the nonvolatile semiconductor memory device.

The electrode layers 40 and the selection gate electrodes 45D and 45S may be silicided. The electrode layers 40 and the selection gate electrodes 45D and 45S that are provided in the embodiment are silicided as examples.

A pair of memory holes MH that extend in the Z-direction is made in the stacked body 41. For example, the memory holes MH are the holes prior to forming the channel body layer 20A and a memory film 30A (described below). The memory holes MH communicate with a hollow portion SP made in the back gate electrode 22 to make a hole having a U-shaped configuration.

The channel body layer 20A is provided inside the memory holes MH. The channel body layer 20A extends through the stacked body 41 in a direction (the Z-direction) in which the stacked body 41 is stacked alternately. The channel body layer 20A is, for example, a silicon-containing layer. The memory film 30A is provided between the channel body layer 20A and the inner wall of the memory holes MH. The memory film 30A is provided between the channel body layer 20A and each of the multiple electrode layers 40.

The memory film 30A has a multilayered structure. For example, the memory film 30A has an ONO (Oxide-Nitride-Oxide) structure in which a silicon nitride film is interposed between silicon oxide films. For example, a charge storage film is provided between a silicon oxide film contacting the electrode layers 40 and a silicon oxide film contacting the channel body layer 20A. The charge storage film includes, for example, silicon nitride.

A channel body layer 20B (a second semiconductor member) is provided inside the back gate electrode 22. For example, the channel body layer 20B is provided inside the hollow portion SP provided inside the back gate electrode 22. The channel body layer 20B is connected to a pair of channel body layers 20A. The channel body layer 20B is, for example, a silicon-containing layer. An insulating film 30B is provided between the channel body layer 20B and the back gate electrode 22. The channel body layer 20A and the channel body layer 20B are generally referred to as a channel body layer 20. The region of the channel body layer 20 on the lower side of the stacked body 41 is referred to as the channel body layer 20B.

A back gate transistor is formed of the back gate electrode 22, the channel body layer 20B, and the insulating film 30B. The insulating film 30B is formed simultaneously with the memory film 30A and has an ONO structure. The memory film 30A and the insulating film 30B are generally referred to as an insulating film 30. The region of the insulating film 30 on the lower side of the stacked body 41 is referred to as the insulating film 30B. Accordingly, the back gate electrode portion 22Cm that is silicided contacts the insulating film 30B.

Although a channel body layer 20 having a pipe-like configuration is shown in FIGS. 1A and 1B as an example, a channel body layer 20 that is not hollow also is included in the first embodiment.

Manufacturing processes of the nonvolatile semiconductor memory device 1 will now be described. Unless otherwise specified, film formation is performed by a method such as CVD (Chemical Vapor Deposition), sputtering, vacuum vapor deposition, ALD (Atomic Layer Deposition), MLD (Molecular Layer Deposition), printing, plating, etc. The patterning of covering films and layers is performed by a method such as photolithography, etching, CMP (Chemical Mechanical Polishing), etc. Also, ion irradiation may be performed as necessary.

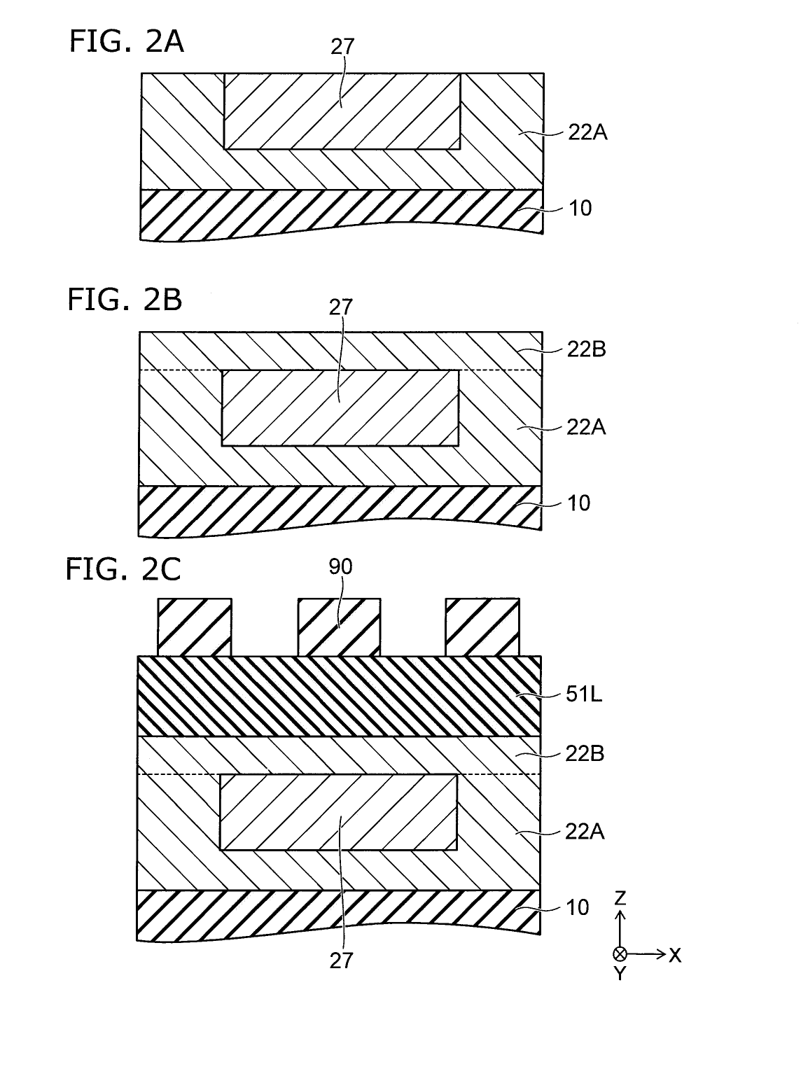

FIG. 2A to FIG. 14 are schematic cross-sectional views showing the manufacturing processes of the nonvolatile semiconductor memory device according to the first embodiment.

As shown in FIG. 2A, the back gate electrode portion 22A is formed on the foundation layer 10. A sacrificial layer 27 is pre-formed selectively in the back gate electrode portion 22A. The sacrificial layer 27 is, for example, non-doped amorphous silicon. The upper surface of the back gate electrode portion 22A and the upper surface of the sacrificial layer 27 are polished by CMP, etc. Thereby, the height of the back gate electrode portion 22A and the height of the sacrificial layer 27 from the foundation layer 10 are the same.

Then, as shown in FIG. 2B, the back gate electrode portion 22B is formed on the back gate electrode portion 22A and on the sacrificial layer 27.

Continuing as shown in FIG. 2C, an insulating layer 51L is formed on the back gate electrode portion 22B. A mask layer 90 is patterned on the insulating layer 51L. A film (not shown) may be formed between the back gate electrode portion 22B and the insulating layer 51L as necessary to increase the adhesion strength between the back gate electrode portion 22B and the insulating layer 51L. The insulating layer 51L may have a multilayered structure. For example, the lower layer of the insulating layer 51L may include silicon oxide, silicon nitride, etc., and the upper layer of the insulating layer 51L may include at least one of Ti, Al, Ta, W, Si, Mo, Mn, Zr, or the like; or the insulating layer 51L may be an oxide film of these metals or a nitride film of these metals.

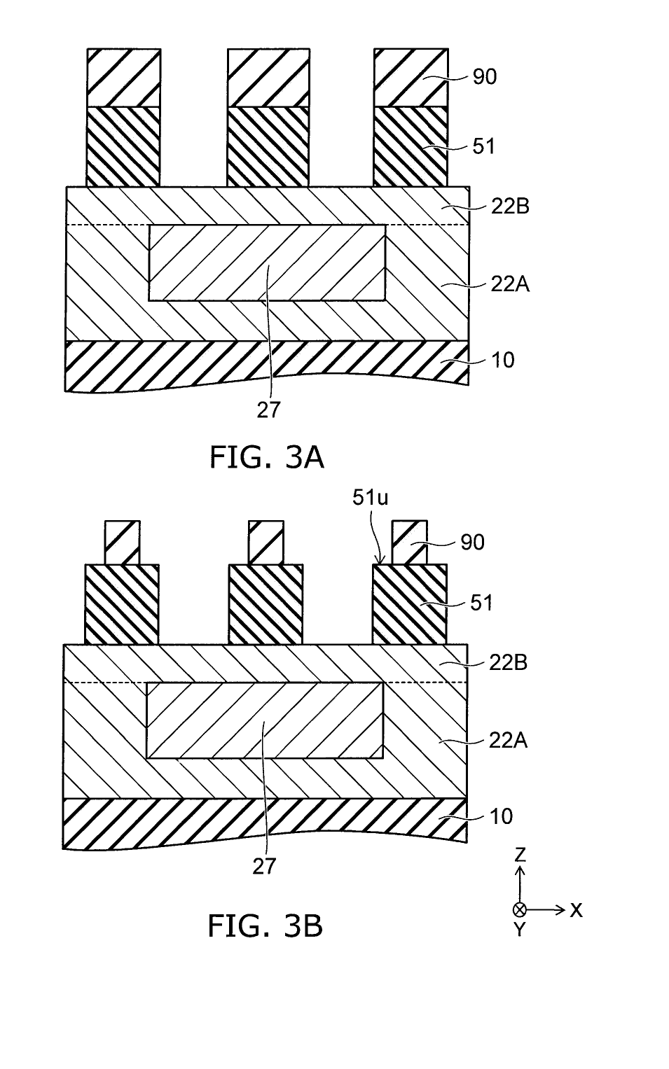

Then, as shown in FIG. 3A, the insulating layer 51L that is not covered with the mask layer 90 is etched. The etching is performed by RIE (Reactive Ion Etching). After the etching, the insulating layer 51L is divided; and the insulating layer 51 is formed.

Continuing as shown in FIG. 3B, wet etching of the mask layer 90 is performed. Thereby, the width of the mask layer 90 in the Y-direction and the length of the mask layer 90 in the Z-direction are contracted. Also, a portion of an upper surface 51u of the insulating layer 51 is exposed from the mask layer 90.

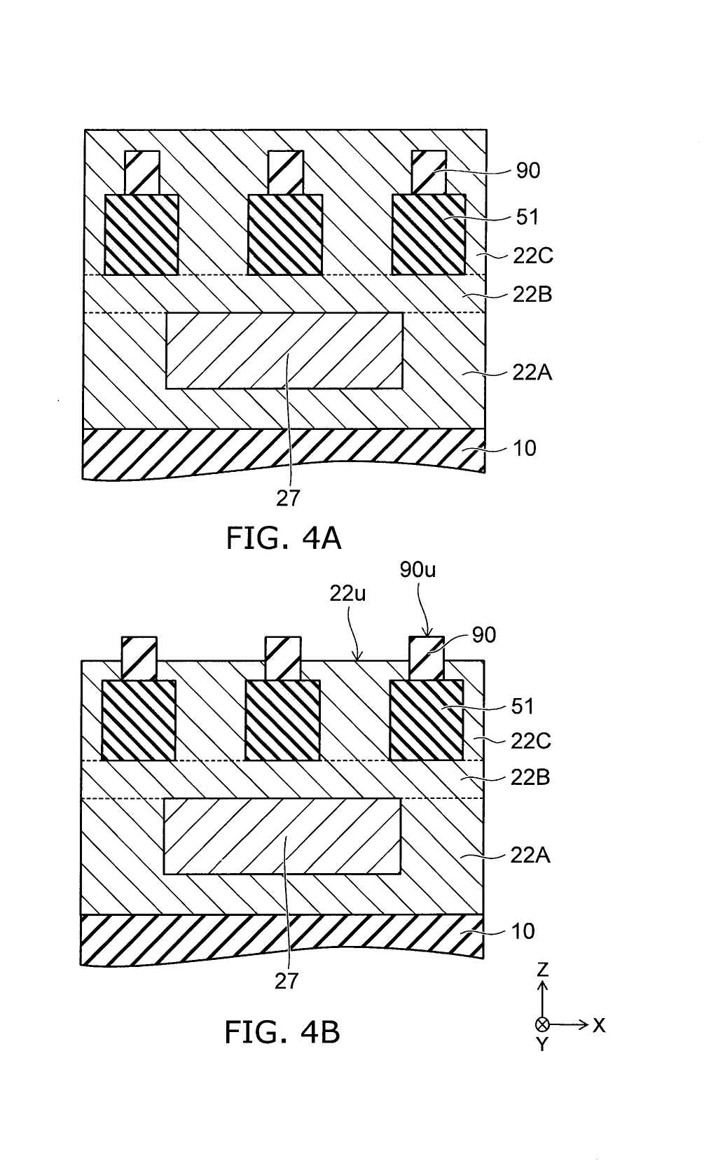

Then, as shown in FIG. 4A, the back gate electrode portion 22C is formed on the back gate electrode portion 22B to cover the insulating layer 51 and the mask layer 90.

Continuing as shown in FIG. 4B, etch-back of the back gate electrode portion 22C is performed. Thereby, an upper surface 22u of the back gate electrode portion 22C becomes lower than an upper surface 90u of the mask layer 90. That is, a portion of the mask layer 90 is exposed from the back gate electrode portion 22C. Subsequently, the mask layer 90 is removed.

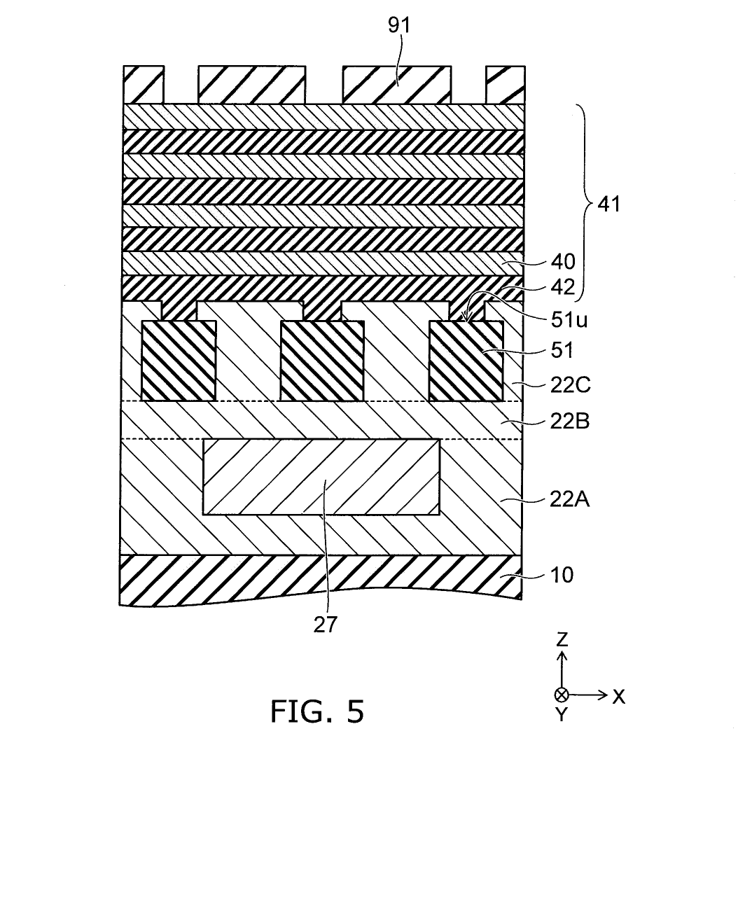

Then, as shown in FIG. 5, the stacked body 41 is formed on the back gate electrode portion 22C and on the insulating layer 51. Here, the insulating layer 42 of the lowermost layer inside the stacked body 41 contacts the insulating layer 51. Further, a mask layer 91 is patterned on the stacked body 41.

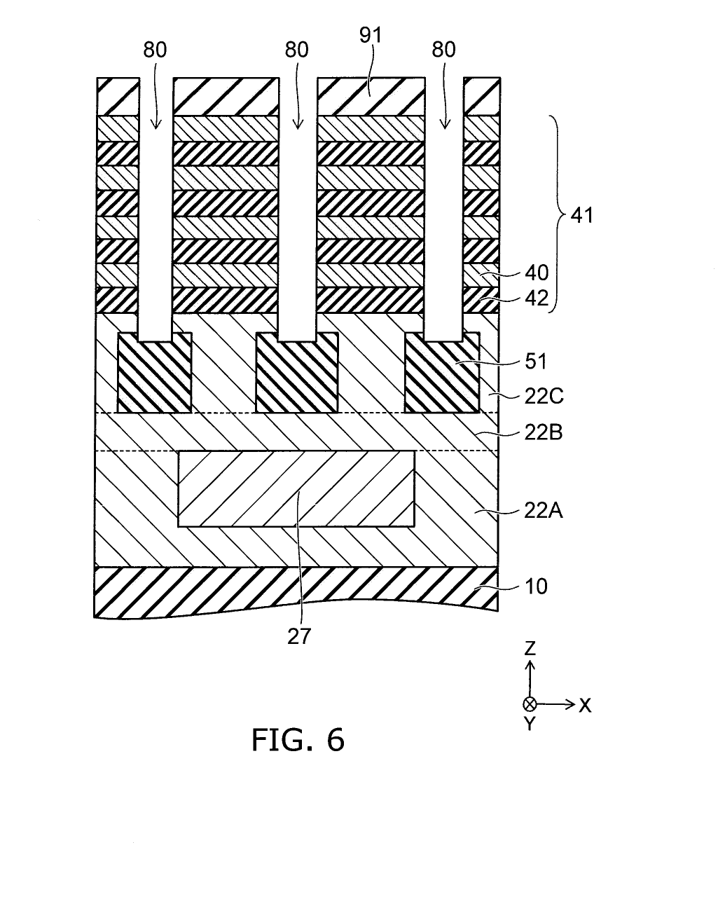

Continuing as shown in FIG. 6, the stacked body 41 that is not covered with the mask layer 91 is etched. The etching is performed by RIE. Thereby, a trench 80 is made in the stacked body 41 to reach the insulating layer 51. The insulating layer 51 functions as an etching stopper layer in the etching process. Subsequently, the mask layer 91 is removed.

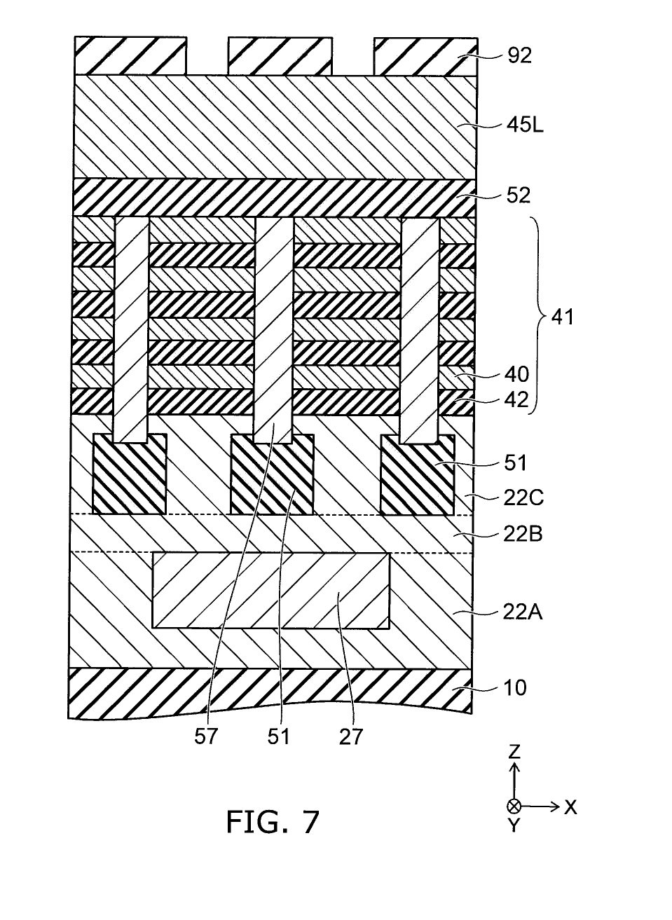

Then, as shown in FIG. 7, a sacrificial layer 57 is formed inside the trench 80. The sacrificial layer 57 includes, for example, silicon nitride, a conductor including Si, silicon oxide, etc. The insulating layer 52 is formed on the stacked body 41 and on the sacrificial layer 57. A selection gate electrode layer 45L is formed on the insulating layer 52. A mask layer 92 is patterned on the selection gate electrode layer 45L.

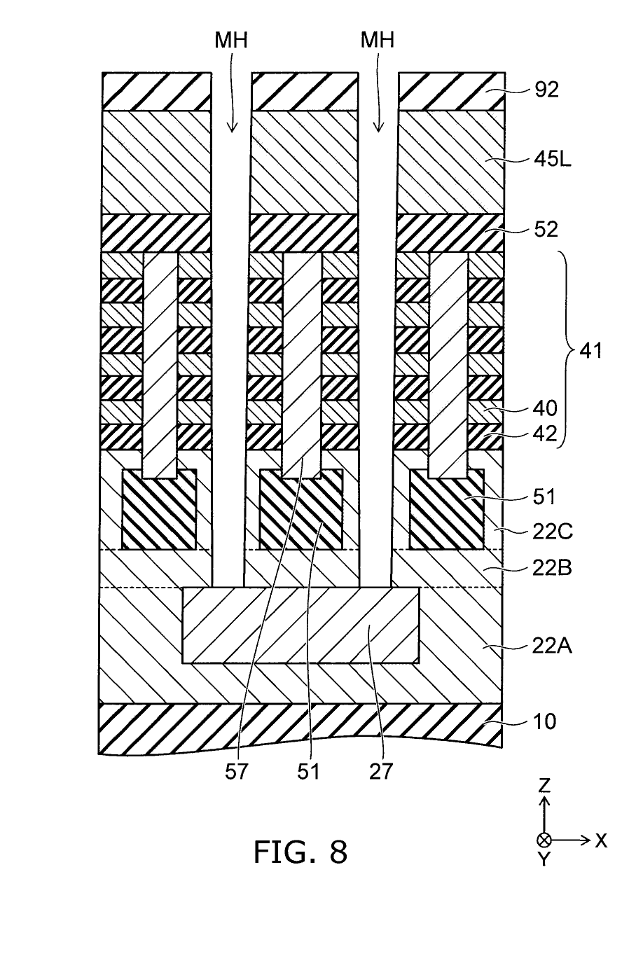

Continuing as shown in FIG. 8, the selection gate electrode layer 45L that is not covered with the mask layer 92 is etched; and the insulating layer 52, the stacked body 41, the back gate electrode portion 22C, and the back gate electrode portion 22B to be etched under the selection gate electrode layer 45L are etched. The etching is performed by RIE. Thereby, a pair of memory holes MH is made in the stacked body 41. The memory holes MH are made from the selection gate electrode layer 45L toward the foundation layer 10 to reach the sacrificial layer 27.

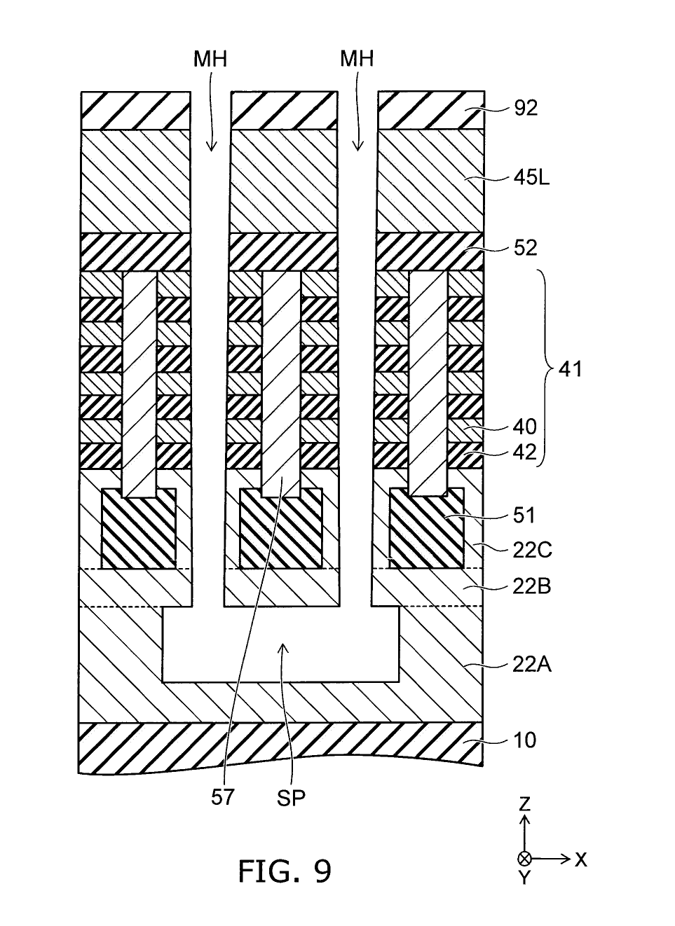

Then, as shown in FIG. 9, a chemical liquid that selectively dissolves the sacrificial layer 27 is introduced to the memory holes MH. For example, an alkaline solution such as KOH, etc., is introduced to the memory holes MH; and the sacrificial layer 27 is removed through the memory holes MH.

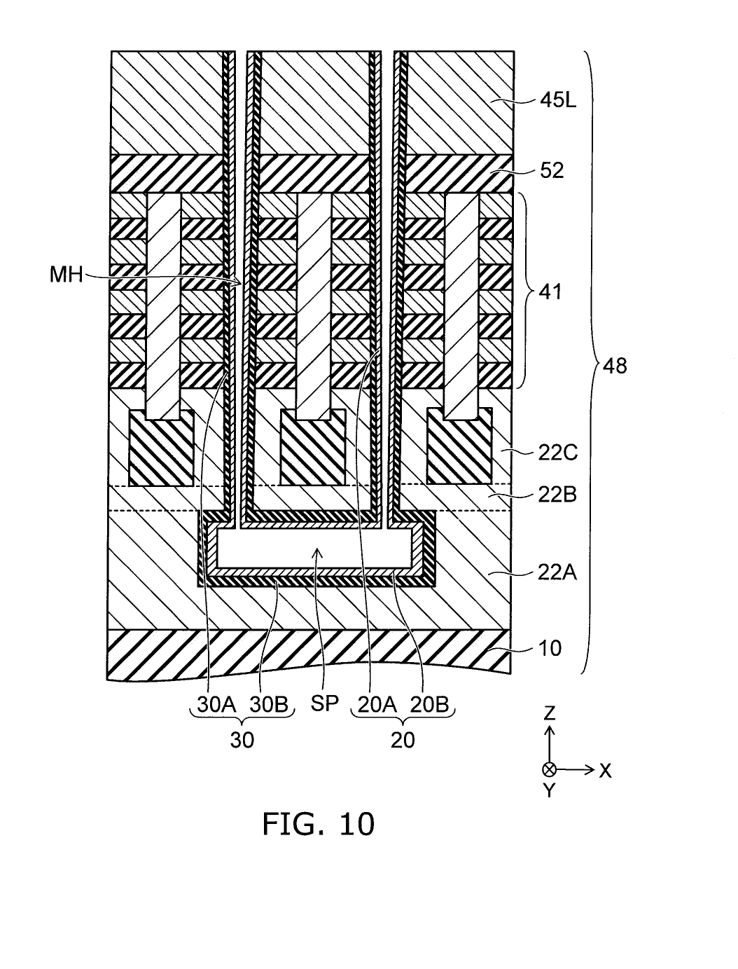

Continuing as shown in FIG. 10, the memory film 30A is formed on the inner walls of the memory holes MH; and further, the channel body layer 20A is formed. Also, the insulating film 30B is formed on the inner wall of the hollow portion SP; and further, the channel body layer 20B is formed. Here, the memory film 30A and the insulating film 30B are formed simultaneously. Also, the channel body layer 20A and the channel body layer 20B are formed simultaneously. Heating of the memory film 30A and the insulating film 30B is performed as necessary.

Thereby, a structural body 48 is formed to include the foundation layer 10, the stacked body 41, the back gates electrode portions 22A to 22C, the channel body layer 20A, the memory film 30A, the channel body layer 20B, the insulating film 30B, the insulating layer 51, and the selection gate electrode layer 45L.

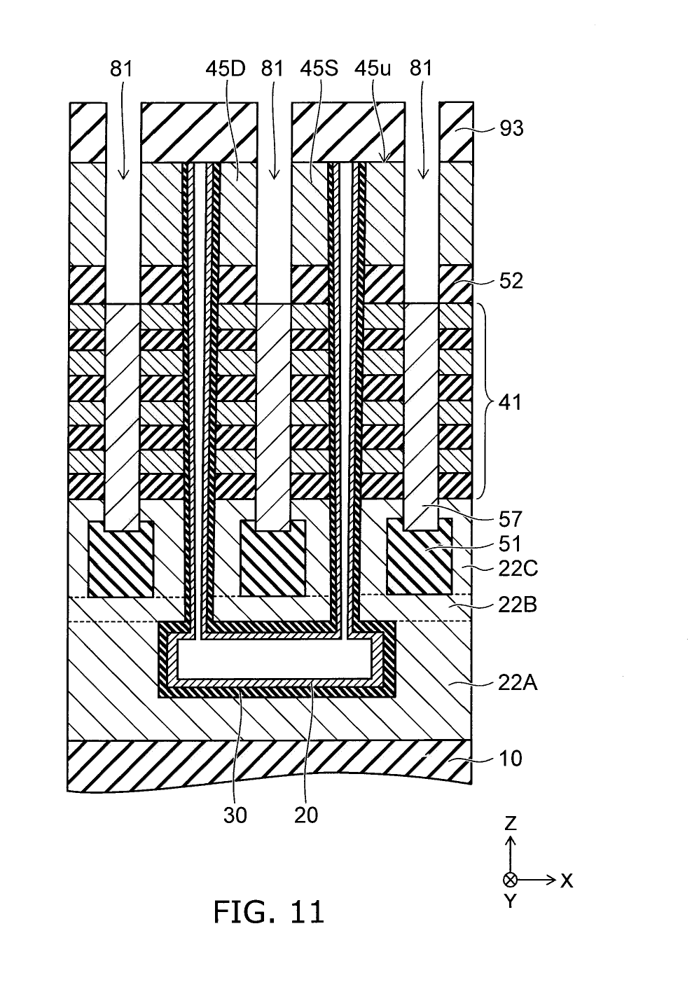

Then, as shown in FIG. 11, a mask layer 93 is patterned on the selection gate electrode layer 45L. Then, the selection gate electrode layer 45L that is not covered with the mask layer 93 is etched; and the insulating layer 52 that is to be etched under the selection gate electrode layer 45L is etched. The etching is RIE. Thereby, a trench 81 is made from an upper surface 45u of the selection gate electrode layer 45L to reach the sacrificial layer 57. After the etching, the selection gate electrode layer 45L is divided into the selection gate electrode 45D and the selection gate electrode 45S.

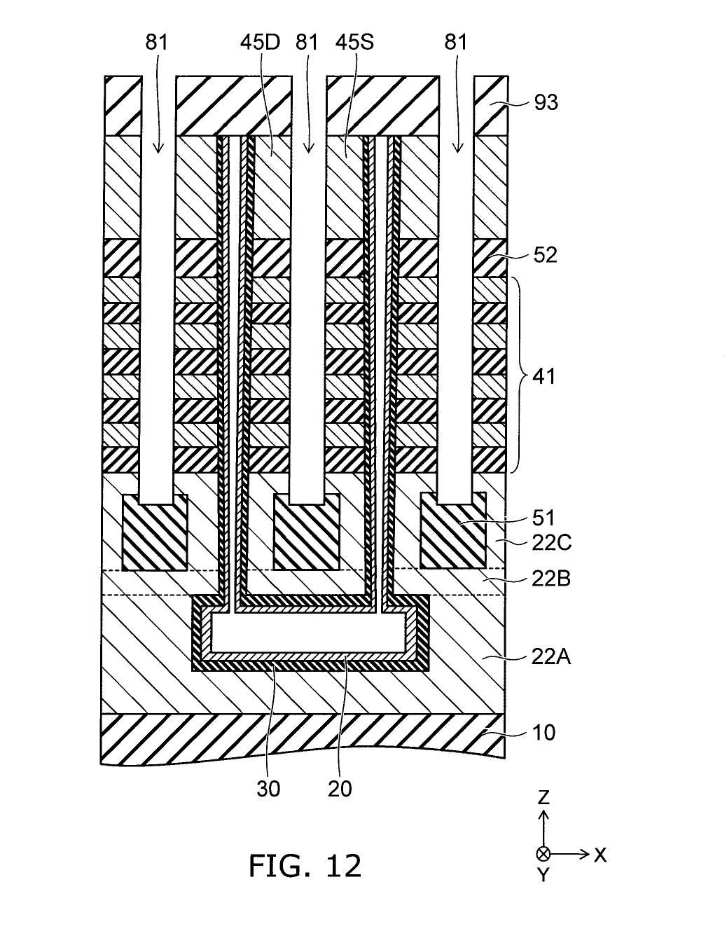

Continuing as shown in FIG. 12, in the case where the sacrificial layer 57 includes silicon nitride, for example, a phosphoric acid (H₃PO₄) solution or the like is introduced to the trench 81. Thereby, the sacrificial layer 57 is removed through the trench 81. The trench 81 is extended further toward the foundation layer 10 side by the removal of the sacrificial layer 57. That is, the trench 81 is made from the upper surface of the stacked body 41 to reach the insulating layer 51. Subsequently, the mask layer 93 is removed.

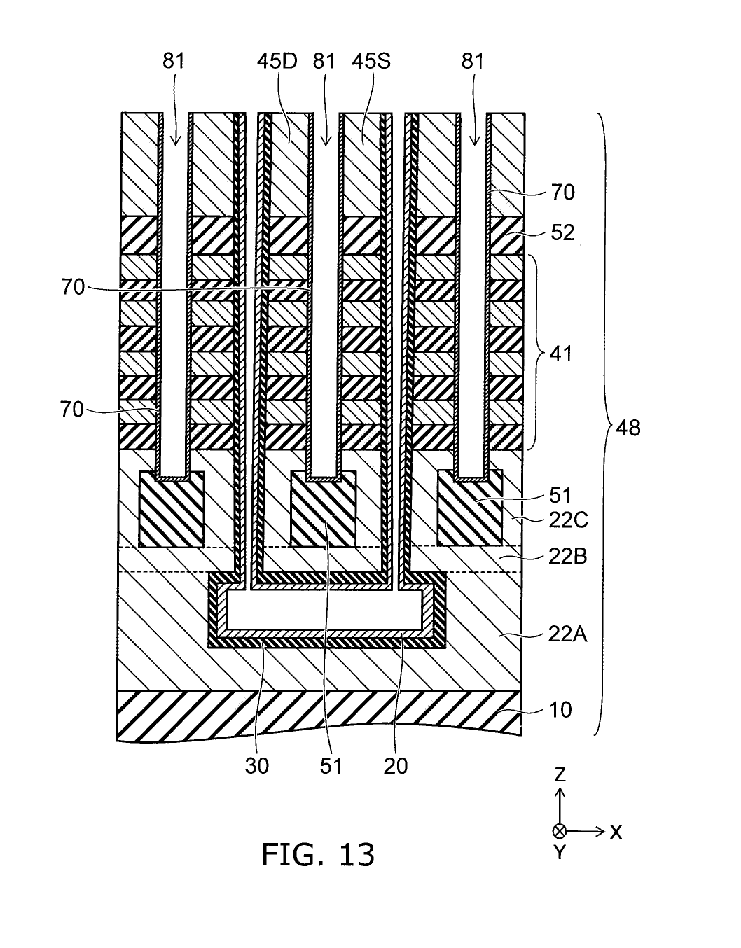

Then, as shown in FIG. 13, a metal film 70 that includes at least one of nickel (Ni), cobalt (Co), or the like is formed on the inner wall of the trench 81. The metal film 70 is adhered to not only a portion of the back gate electrode portion 22C but also the electrode layers 40, the selection gate electrode 45D, and the selection gate electrode 45S. Then, the structural body 48 and the metal film 70 are heated.

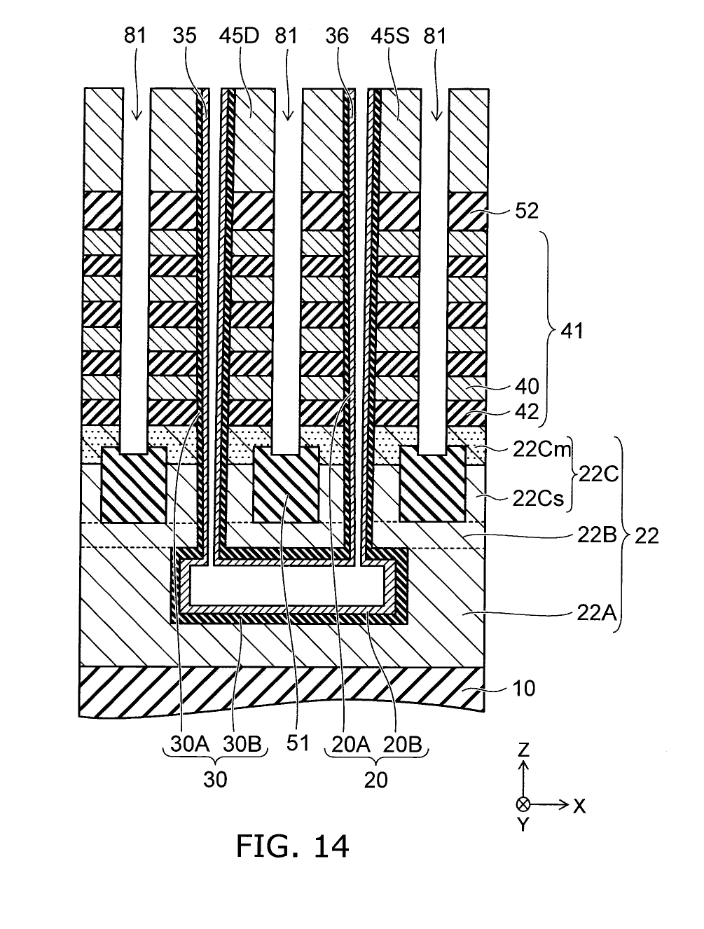

Thereby, metal is diffused from the stacked body 41 side to the foundation layer 10 side, so that a portion of the back gate electrode portion 22C on the side of the stacked body is silicided as shown in FIG. 14. The silicided region is referred to as the back gate electrode portion 22Cm. The back gate electrode portion 22Cm includes, for example, cobalt silicide (CoSiₓ), nickel silicide (NiSiₓ), etc. The portion not being silicided in the back gate electrode portion 22C is the back gate electrode portion 22Cs. The back gate electrode portion 22Cm contacts the insulating layer 51. Also, the electrode layers 40 and the selection gate electrodes 45D and 45S are silicided. After the siliciding, the metal film 70 that remains at the inner wall of the trench 81 as residue is removed by, for example, acid cleaning, etc. Subsequently, for example, the insulating layer 50 is formed inside the trench 81 as shown in FIG. 1A.

In the nonvolatile semiconductor memory device 1, a portion of the back gate electrode 22 is silicided. Thereby, the resistance of the back gate electrode 22 is lower than that of a back gate that is not silicided. That is, in the nonvolatile semiconductor memory device 1, the controllability of the back gate transistor is even better.

### Second Embodiment

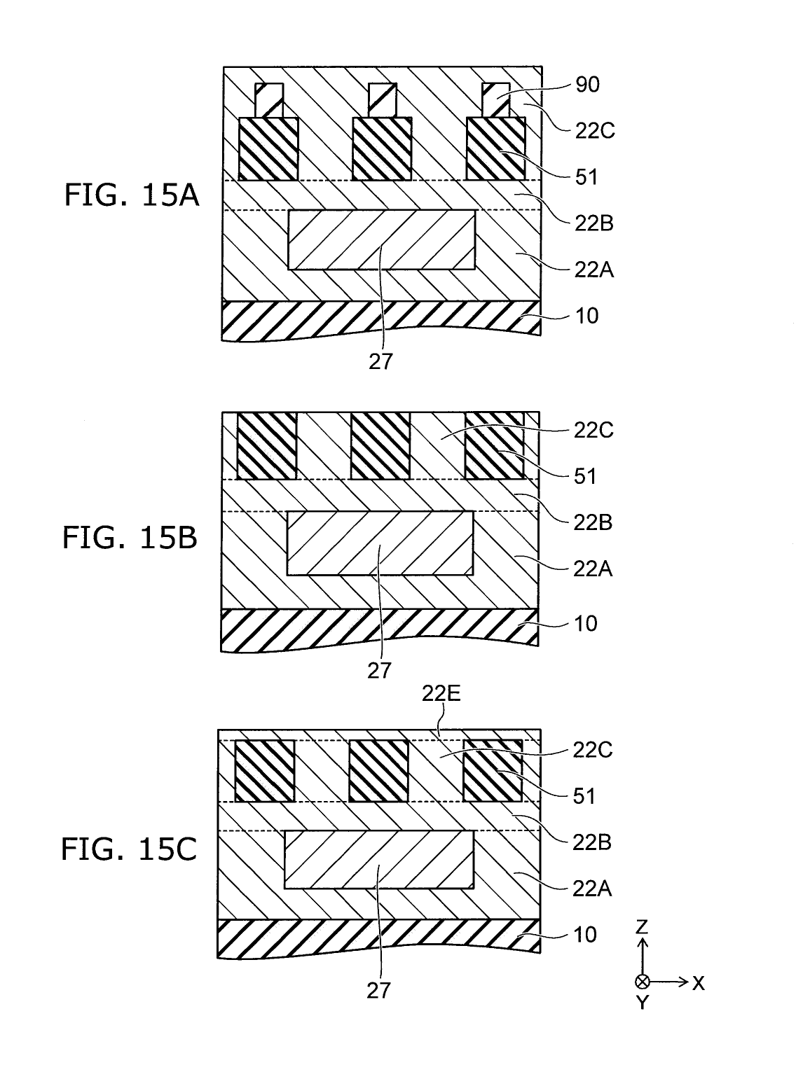

FIG. 15A to FIG. 17 are schematic cross-sectional views showing manufacturing processes of a nonvolatile semiconductor memory device according to a second embodiment.

The same state as FIG. 4A is prepared as shown in FIG. 15A.

Then, as shown in FIG. 15B, the mask layer 90 and a portion of the back gate electrode portion 22C are removed by CMP or etching. Thereby, the height of the upper surface of the back gate electrode portion 22C from the foundation layer 10 and the height of the upper surface of the insulating layer 51 from the foundation layer 10 are the same.

Continuing as shown in FIG. 15C, a back gate electrode portion 22E is formed on the back gate electrode portion 22C and on the insulating layer 51.

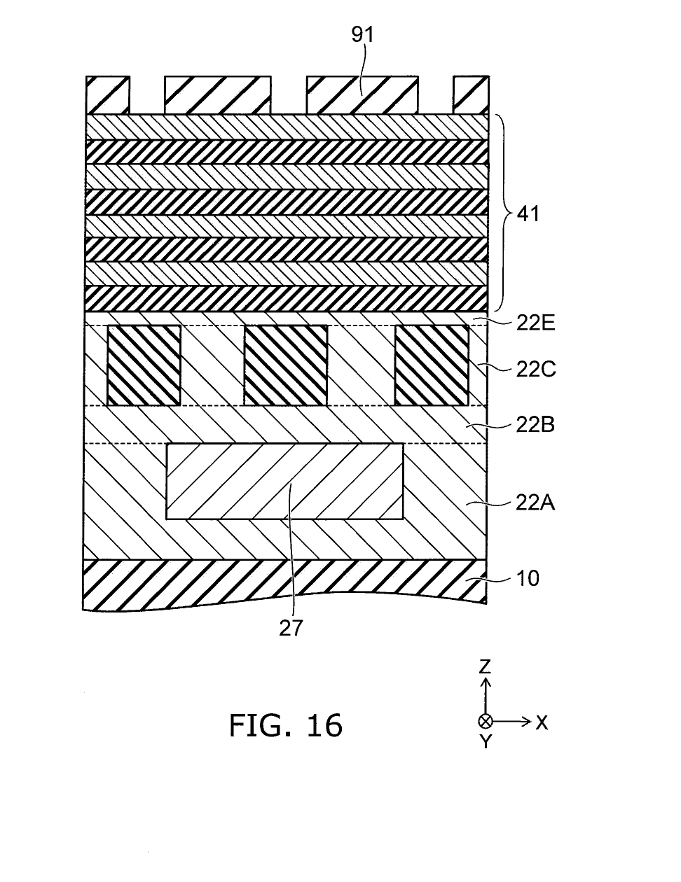

Then, as shown in FIG. 16, the stacked body 41 is formed on the back gate electrode portion 22E. Further, the mask layer 91 is patterned on the stacked body 41.

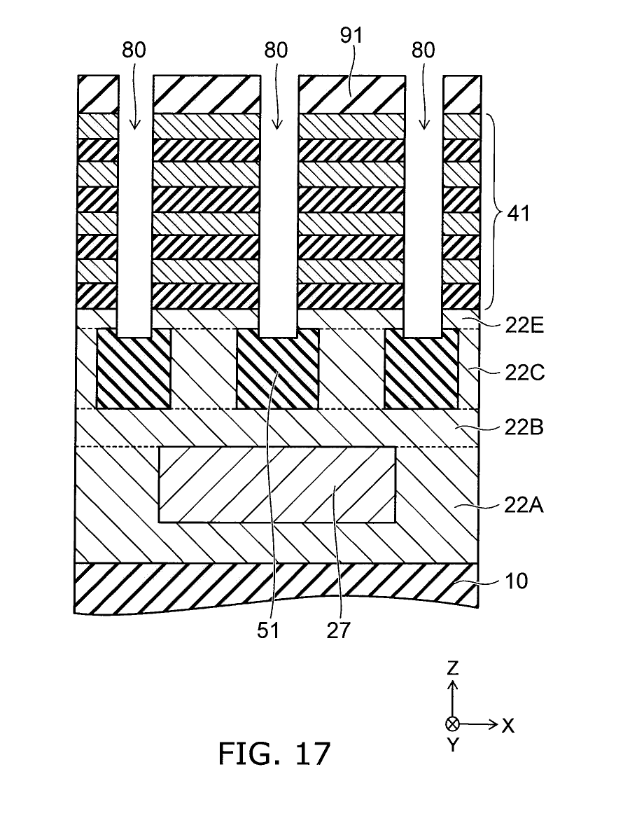

Continuing as shown in FIG. 17, the stacked body 41 that is not covered with the mask layer 91 is etched. The etching is performed by RIE. Thereby, the trench 80 is made in the stacked body 41 to reach the insulating layer 51.

Here, the layer that is the combination of the back gate electrode portion 22E and the back gate electrode portion 22C after the etching is substantially the same as the back gate electrode portion 22C shown in FIG. 6. That is, thereafter, the nonvolatile semiconductor memory device 1 can be formed by performing the processes shown in FIG. 7 to FIG. 14.

### Third Embodiment

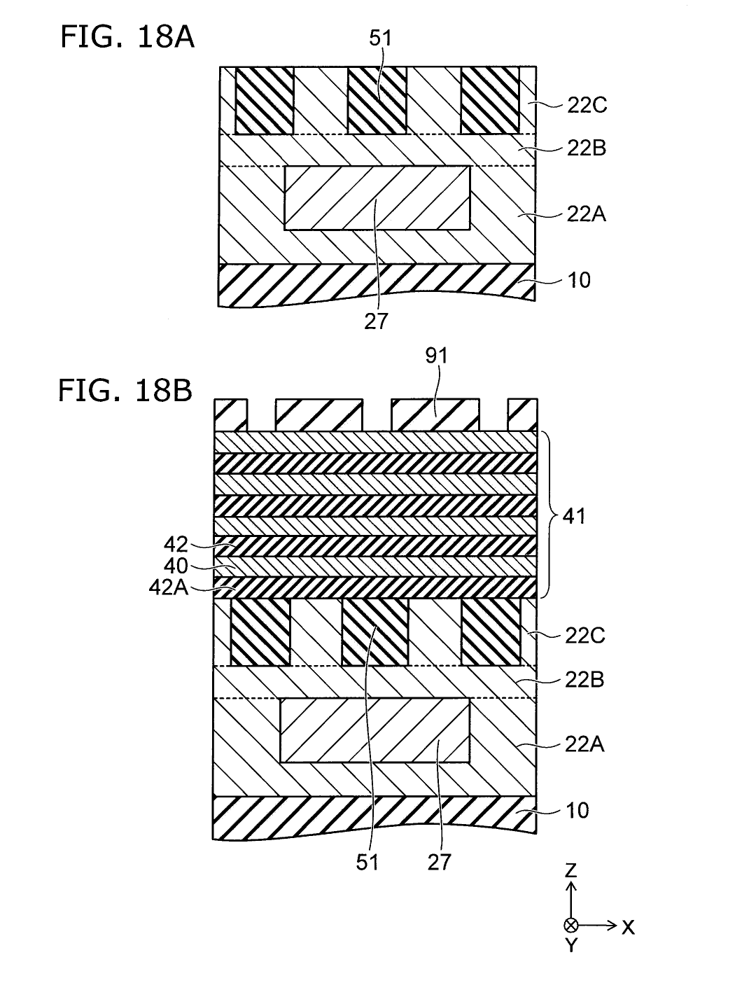

FIG. 18A to FIG. 23 are schematic cross-sectional views showing manufacturing processes of a nonvolatile semiconductor memory device according to a third embodiment.

The same state as FIG. 15B is prepared as shown in FIG. 18A.

Then, as shown in FIG. 18B, the stacked body 41 is formed on the back gate electrode portion 22C and on the insulating layer 51. The mask layer 91 is formed on the stacked body 41.

When forming an insulating layer 42A of the lowermost layer of the stacked body 41, the insulating layer 42A is formed using conditions that are different from the conditions when forming the insulating layers 42 other than the insulating layer 42A. For example, the film properties of the insulating layers 42 and 42A are adjusted so that the etching rate of the insulating layer 42A is faster than the etching rate of the insulating layers 42 when the insulating layer 42A and the insulating layers 42 are immersed in a dilute hydrofluoric acid solution.

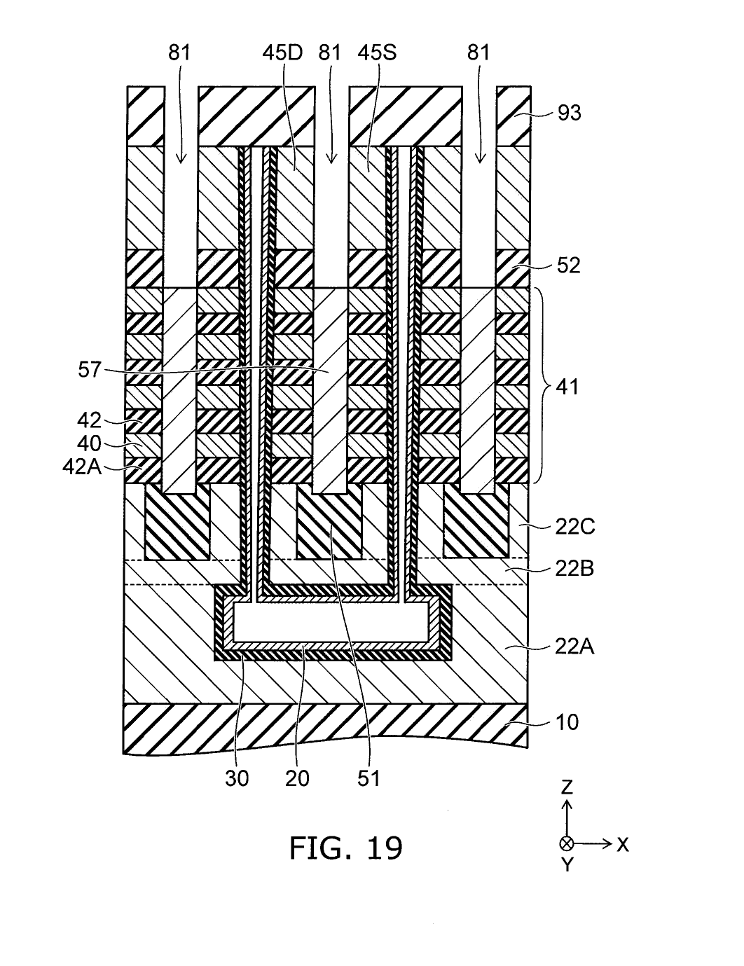

Subsequently, the state shown in FIG. 19 is obtained by performing the same processing as the processes shown in FIG. 6 to FIG. 11.

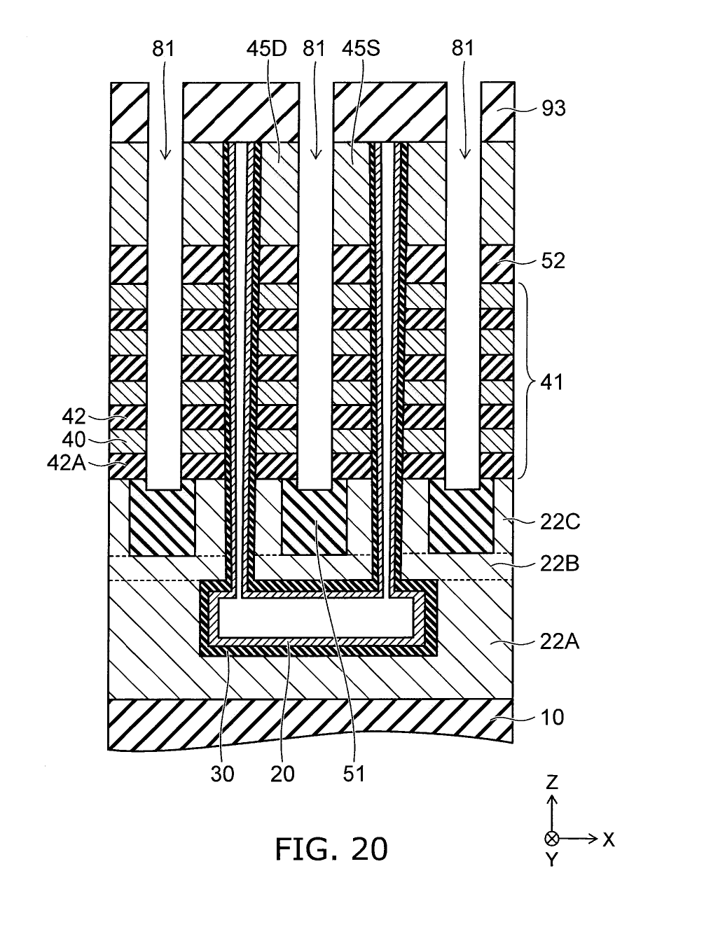

Then, as shown in FIG. 20, in the case where the sacrificial layer 57 includes silicon nitride, for example, a phosphoric acid solution or the like is introduced to the trench 81. Thereby, the sacrificial layer 57 is removed through the trench 81. The trench 81 is further extended toward the foundation layer 10 side by the removal of the sacrificial layer 57.

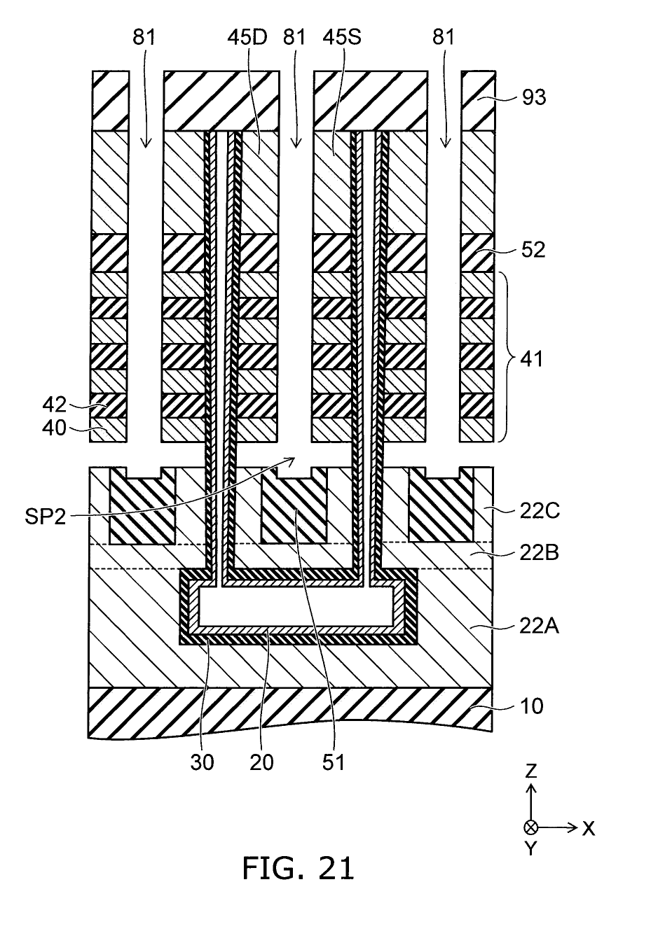

Continuing as shown in FIG. 21, for example, a dilute hydrofluoric acid solution or the like is introduced to the trench 81. As described above, the etching rate of the insulating layer 42A is faster than the etching rate of the insulating layers 42 for the dilute hydrofluoric acid solution. Accordingly, in the stacked body 41, the insulating layer 42A that contacts the back gate electrode portion 22C is removed through the trench 81 without removing the insulating layers 42. Subsequently, the mask layer 93 is removed.

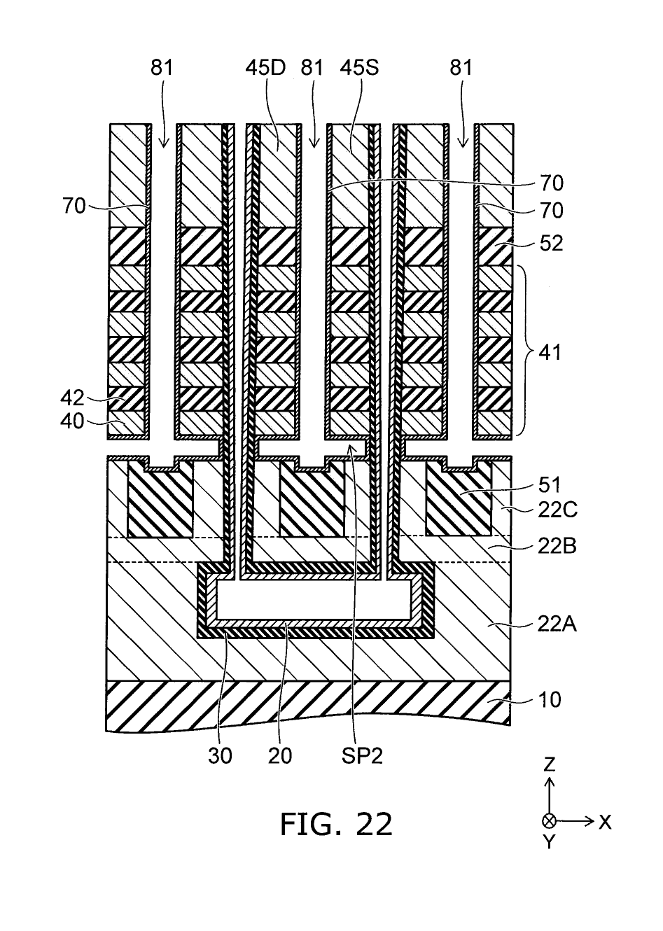

Then, as shown in FIG. 22, the metal film 70 that includes at least one of nickel (Ni), cobalt (Co), or the like is formed on the inner wall of the trench 81 and on the inner wall of a hollow portion SP2 made by removing the insulating layer 42A. The metal film 70 is adhered to not only a portion of the back gate electrode portion 22C but also the electrode layers 40, the selection gate electrode 45D, and the selection gate electrode 45S.

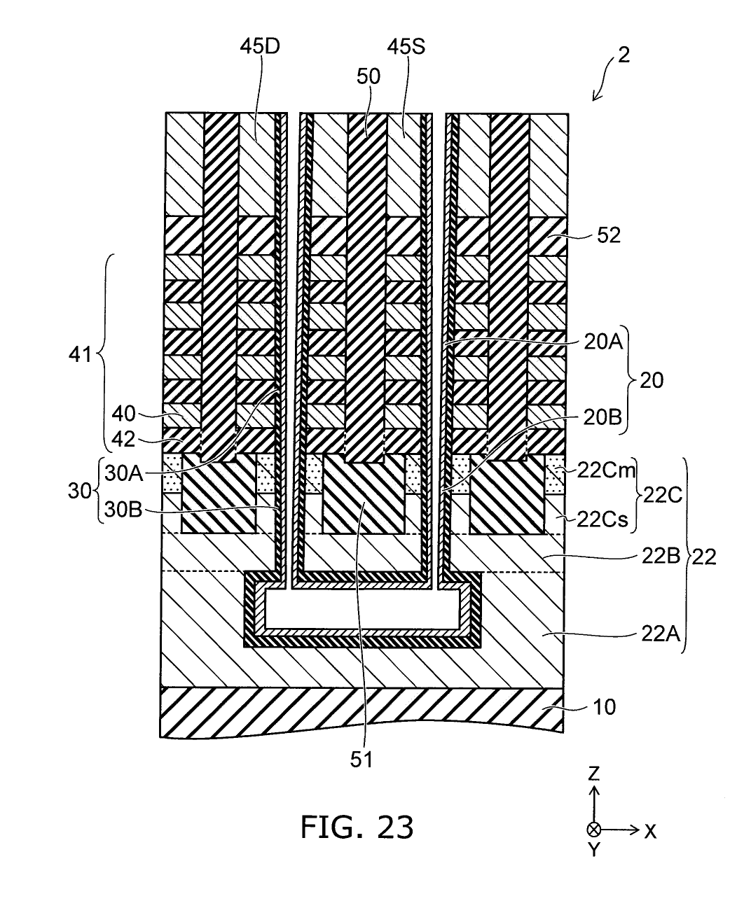

Subsequently, siliciding of the electrode layers 40, the selection gate electrodes 45D and 45S, and the back gate electrode portion 22C is performed by heating. After the siliciding, the metal film 70 that remains on the inner wall of the trench 81 and the inner wall of the hollow portion SP2 as residue is removed by, for example, acid cleaning, etc. Subsequently, the insulating layer 50 is formed inside the trench 81 and inside the hollow portion SP2. This state is shown in FIG. 23.

In the nonvolatile semiconductor memory device 2 shown in FIG. 23, the insulating layer that is formed again inside the hollow portion SP2 is used as the insulating layer 42. In the nonvolatile semiconductor memory device 2, the region of the back gate electrode 22 between the insulating film 30B and the insulating layer 51 is silicided on the side of the stacked body 41. The silicided region is referred to as the back gate electrode portion 22Cm. The back gate electrode portion 22Cm includes, for example, cobalt silicide (CoSiₓ), nickel silicide (NiSiₓ), etc. Also, in the nonvolatile semiconductor memory device 2, a silicided layer is not provided on the insulating layer 51.

Thus, in the nonvolatile semiconductor memory device 2, a portion of the back gate 22 electrode is silicided. Thereby, the resistance of the back gate electrode 22 is lower than that of a back gate that is not silicided. That is, in the nonvolatile semiconductor memory device 2, the controllability of the back gate transistor is even better.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device, comprising:
a foundation layer;
a stacked body provided on the foundation layer, each of a plurality of first insulating layers and each of a plurality of electrode layers being stacked alternately in the stacked body;
a first layer provided between the stacked body and the foundation layer, the first layer including semiconductor, one portion of the first layer on a side of the stacked body including metal;
a pair of first semiconductor members extending through the stacked body in a stacking direction of the stacked body;
a memory film provided between each of the first semiconductor members and each of the plurality of electrode layers;
a second semiconductor member provided inside the first layer and connected to the pair of first semiconductor members; and
an insulating film provided between the second semiconductor member and the first layer.

2. The device according to claim 1, further comprising:
a second insulating layer provided in the first layer, and
a region of the first layer between the second insulating layer and the stacked body and a portion of the first layer extending over an interior from the region including the metal.

3. The device according to claim 1, wherein
at least a portion of the first layer between the insulating film and the second insulating layer is silicided, the at least the portion of the first layer is contact with the stacked body.

4. The device according to claim 1, wherein
the one portion contacts the stacked body.

5. The device according to claim 2, wherein
the second insulating layer does not contact the stacked body.

6. The device according to claim 2, wherein
the second insulating layer contacts the stacked body.

7. A method for manufacturing a nonvolatile semiconductor memory device, comprising:
forming a structural body, the structural body including a foundation layer, a stacked body provided on the foundation layer, a first layer provided between the stacked body and the foundation layer, the first layer including semiconductor, a pair of first semiconductor members, a memory film, a second semiconductor member provided inside the first layer, and an insulating film provided between the second semiconductor member and the first layer, each of a plurality of first insulating layers and each of a plurality of electrode layers being stacked alternately in the stacked body, the pair of first semiconductor members extending through the stacked body in a stacking direction of the stacked body, the memory film being provided between each of the first semiconductor members and each of the plurality of electrode layers, the second semiconductor member being connected to the pair of first semiconductor members, the structural body including a second insulating layer in the first layer;
forming a trench from an upper surface of the stacked body to reach the second insulating layer;
forming a metal film inside the trench; and
siliciding a portion of the first layer contacting the stacked body by heating the structural body and the metal film.

8. The method according to claim 7, wherein
a sacrificial layer is formed from the upper surface of the stacked body to reach the second insulating layer before the forming of the trench.

9. The method according to claim 8, wherein
the pair of first semiconductor members, the memory film, the second semiconductor member, and the insulating film are formed after the forming of the sacrificial layer.

10. The method according to claim 8, wherein
the trench is formed by removing the sacrificial layer.

11. The method according to claim 7, wherein
the forming of the structural body includes:
exposing a portion of the second insulating layer from the first layer; and
forming the stacked body on the first layer.

12. The method according to claim 7, further comprising removing a first insulating layer of the plurality of first insulating layers through the trench after the forming of the trench and before the forming of the metal film, the first insulating layer contacting the first layer.

13. The method according to claim 12, wherein
an etching rate of the first insulating layer contacting the first layer is faster than an etching rate for the acid solution of the first insulating layers other than the first insulating layer contacting the first layer for an acid solution.

14. The method according to claim 7, wherein
the second insulating layer is provided in the first layer, and
a region of the first layer between the second insulating layer and the stacked body is silicided by the heating, and a portion of the first layer extending over an interior from the region is silicided by the heating.

15. The method according to claim 7, wherein
at least a portion of the first layer between the insulating film and the second insulating layer is silicided by the heating, the at least the portion of the first layer is contact with the stacked body.
